(19) United States
(12) Patent Application Publication
(10) Pub. No.: US 2025/0006865 A1
(43) Pub. Date: Jan. 2, 2025

(54) DISPLAY ELEMENT AND MANUFACTURING METHOD THEREOF

(71) Applicant: AUO Corporation, Hsin-Chu (TW)

(72) Inventors: Shu-Jiang LIU, Hsin-Chu (TW); Han-Chung LAI, Hsin-Chu (TW); Rong-Sheng TSAI, Hsin-Chu (TW); Wen-Jen LI, Hsin-Chu (TW); Jia-Hao HSU, Hsin-Chu (TW); Kun-Cheng TIEN, Hsin-Chu (TW)

(21) Appl. No.: 18/533,285

(22) Filed: Dec. 8, 2023

(30) Foreign Application Priority Data
Jun. 27, 2023 (TW) 112123854

(51) Int. Cl. H01L 33/38; H01L 25/075; H01L 27/15; H01L 33/06; H01L 33/10; H01L 33/62

(52) U.S. Cl. CPC H01L 33/38; H01L 25/0753; H01L 27/156; H01L 33/06; H01L 33/10; H01L 33/62; H01L 2933/0016

(57) ABSTRACT

A display element includes a first spacer, a second spacer, at least one first electrode, a second electrode, at least one LED structure, a reflective layer, a first transparent molding layer and a transparent conductive layer. The second spacer is located on one side of the first spacer. The first electrode is surrounded by the first spacer. The second electrode is surrounded by the second spacer. The LED structure is located on the first electrode. The reflective layer is located on a sidewall of the first spacer facing the LED structure. The first transparent molding layer is located on the reflective layer and surrounds the LED structure. The transparent conductive layer is located on the top surface of the second semiconductor layer and the top surface of the first transparent molding layer, and extends to the second electrode.

### RELATED APPLICATIONS

This application claims priority to Taiwan Application Serial Number 112123854, filed Jun. 27, 2023, which is herein incorporated by reference.

### BACKGROUND

### Field of Invention

The present disclosure relates to a display element and a manufacturing method of a display element.

### Description of Related Art

With the rapid development of the electronic technology, display devices have been widely used in people's lives, such as mobile phones or computers. Among these products, the unit area of each light-emitting element becomes smaller and smaller as the resolution of the light-emitting elements increases. While the size of a light-emitting diode (LED) is miniaturized, a P electrode and an N electrode on the same side are designed to be too close to each other, which is prone to cause a short-circuit problem. Also, since the two electrodes are on the same side, a larger cabling area is required, so the resolution is difficultly improved.

A general way to solve the above problems is to use a vertical micro-LED (Vertical microLED) component which has a P electrode and an N electrode on different sides in a vertical direction, so a short circuit problem and a problem that the resolution is difficultly improved will not occur. However, a vertical micro-LED is of a five-sided light-emitting structure in which only upward emitted-light is effective emitted-light, so the light emission efficiency is difficultly improved; and in existing processes, each of LED components cannot be tested at the completion of the LED component, thereby resulting in difficult debugging.

### SUMMARY

One aspect of the present disclosure provides a display element.

According to one embodiment of the present disclosure, a display element includes a first spacer, a second spacer, at least one first electrode, a second electrode, at least one light-emitting diode (LED) structure, a reflective layer, a first transparent molding layer and a transparent conductive layer. The second spacer is located on one side of the first spacer. The first electrode is surrounded by the first spacer. The second electrode is surrounded by the second spacer. The LED structure is located on the first electrode, and includes a first semiconductor layer, a multi-quantum well layer and a second semiconductor layer. The first semiconductor layer is located on the first electrode. The multi-quantum well layer is located on the first semiconductor layer. The second semiconductor layer is located on the multi-quantum well layer. The reflective layer is located on a sidewall of the first spacer facing the LED structure. The first transparent molding layer is located on the reflective layer and surrounds the LED structure, where a top surface of the second semiconductor layer is higher than a top surface of the first transparent molding layer. The transparent conductive layer is located on the top surface of the first transparent molding layer and the top surface of the second semiconductor layer, and extends to the second electrode.

In one embodiment of the present disclosure, the sidewall of the first spacer is a stepped surface or a concave surface.

In one embodiment of the present disclosure, an included angle between the sidewall of the first spacer and a lower surface is 30-55 degrees.

In one embodiment of the present disclosure, the display element further includes a light-absorbing structure. The light-absorbing structure is located on the transparent conductive layer and surrounds a top portion of the second semiconductor layer.

In one embodiment of the present disclosure, the display element further includes a second transparent molding layer. The second transparent molding layer is located on the transparent conductive layer and surrounded by the light-absorbing structure.

In one embodiment of the present disclosure, the display element further includes a substrate. The substrate is located on the second transparent molding layer.

In one embodiment of the present disclosure, the substrate has a light-absorbing layer inside, and the light-absorbing layer is located on the light-absorbing structure.

In one embodiment of the present disclosure, the substrate has a light-reflective layer inside, and the light-reflective layer is located on a sidewall of the light-absorbing layer.

In one embodiment of the present disclosure, the substrate has a light-reflective layer inside, and the light-reflective layer is located on the light-absorbing structure.

In one embodiment of the present disclosure, the substrate has a thickness of less than 0.5 mm.

In one embodiment of the present disclosure, the reflective layer, the first electrode and the second electrode are formed by a same film layer.

In one embodiment of the present disclosure, there are three LED structures arranged in a column, the three LED structures are a red LED structure, a green LED structure and a blue LED structure respectively, there are three first electrodes, the first semiconductor layers of the three LED structures are electrically connected to the three first electrodes respectively, and the second semiconductor layers of the three LED structures are electrically connected to the second electrode.

In one embodiment of the present disclosure, there are a plurality of LED structures arranged in a plurality of columns, and the LED structures in each of the columns include a red LED structure, a green LED structure and a blue LED structure, there are a plurality of first electrodes, the first semiconductor layers of the LED structures are electrically connected to the first electrodes respectively, and the second semiconductor layers of the LED structures are electrically connected to the second electrode respectively.

Another aspect of the present disclosure provides a manufacturing method of a display element.

According to one embodiment of the present disclosure, a manufacturing method of a display element includes: forming a temporary jointing layer on a carrier plate; forming a first spacer and a second spacer on the temporary jointing layer; forming a reflective layer on a sidewall of the first spacer; forming at least one first electrode and a second electrode on the temporary jointing layer, where the first electrode is surrounded by the first spacer and the second electrode is surrounded by the second spacer; forming a LED structure on the first electrode, where the LED structure includes a first semiconductor layer, a multi-quantum well layer and a second semiconductor layer that are stacked in sequence; forming a first transparent molding layer on the reflective layer and around the LED structure, where a top surface of the second semiconductor layer is higher than a top surface of the first transparent molding layer; forming a transparent conductive layer on the top surface of the first transparent molding layer and the top surface of the second semiconductor layer, where the transparent conductive layer extends to the second electrode; and removing the temporary jointing layer and the carrier plate.

In one embodiment of the present disclosure, the manufacturing method of a display element further includes: forming at least one light-absorbing structure on the first transparent molding layer and the transparent conductive layer; forming a second transparent molding layer on the first transparent molding layer and the transparent conductive layer; forming a substrate on the second transparent molding layer; and forming an opening in the substrate.

In one embodiment of the present disclosure, the manufacturing method of a display element further includes: thinning the substrate so that the substrate has a thickness of less than 0.5 mm.

In one embodiment of the present disclosure, the manufacturing method of a display element further includes: filling a light-absorbing material in the opening of the substrate.

In one embodiment of the present disclosure, the manufacturing method of a display element further includes: filling a light-reflective material in the opening of the substrate.

In one embodiment of the present disclosure, the manufacturing method of a display element further includes: plating a light-reflective material on a sidewall of the opening of the substrate; and filling a light-absorbing material in the opening of the substrate.

In the above-mentioned embodiments of the present disclosure, since the display element has the reflective layer facing the LED structure, light from a plurality of original light-emitting surfaces can be concentrated into upward light, thereby effectively providing a better light-emitting efficiency. Moreover, one first electrode, one LED structure and one second electrode of the display element constitute a complete circuit, so individual LED structures can be tested before being bonded to a control circuit substrate, thereby effectively improving the efficiency of debugging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-section diagram of a display element according to one embodiment of the present disclosure;

FIG. 1B is a top view of a first spacer, a second spacer and LED structures of the display element in FIG. 1A;

FIG. 2 is a drawing of partial enlargement of the first spacer according to one embodiment of the present disclosure;

FIG. 3 is a drawing of partial enlargement of the first spacer according to another embodiment of the present disclosure;

FIG. 4 is a drawing of partial enlargement of the display element at block A according to one embodiment of the present disclosure;

FIG. 5 is a drawing of partial enlargement of the display element at block A according to another embodiment of the present disclosure;

FIG. 6 is a drawing of partial enlargement of the display element at block A according to yet another embodiment of the present disclosure;

FIG. 7 is a top view of the display element according to one embodiment of the present disclosure;

FIG. 8 is a top view of a display element according to another embodiment of the present disclosure;

FIG. 9 is a top view of a display element according to yet another embodiment of the present disclosure;

FIG. 10 is a top view of a display element according to still another embodiment of the present disclosure; and

FIGS. 11-16 are cross-section diagrams of the display element during manufacturing according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “about”, “about”, “approximately” or “substantially” generally means within 20 percent, or within 10 percent, or within 20 percent of a given value or range of 5. Numerical quantities given herein are approximations, indicating that the use of terms such as “about,” “approximately,” “approximately,” or “substantially” can be inferred when not explicitly stated.

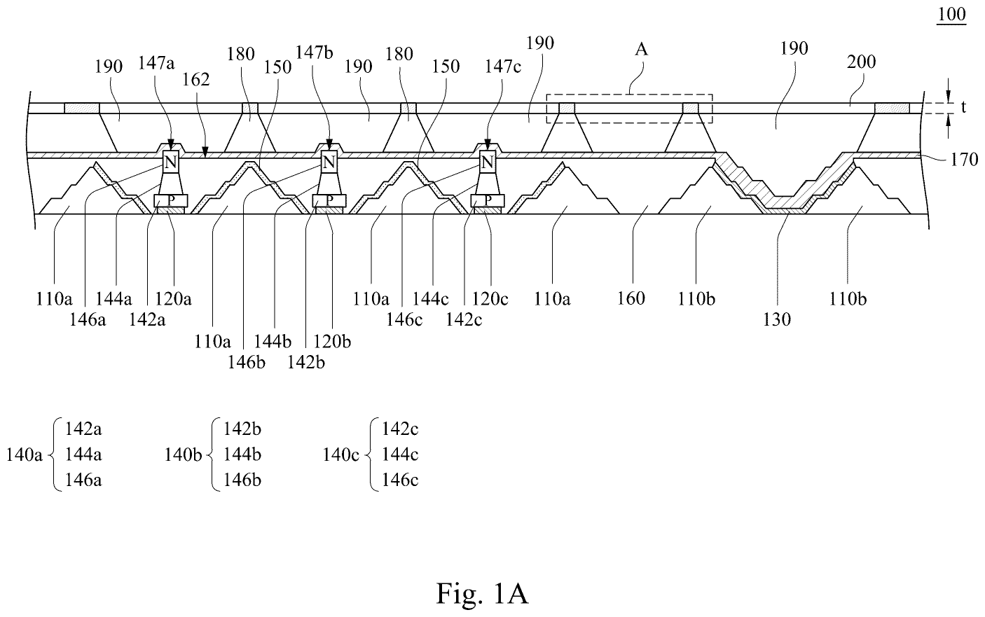

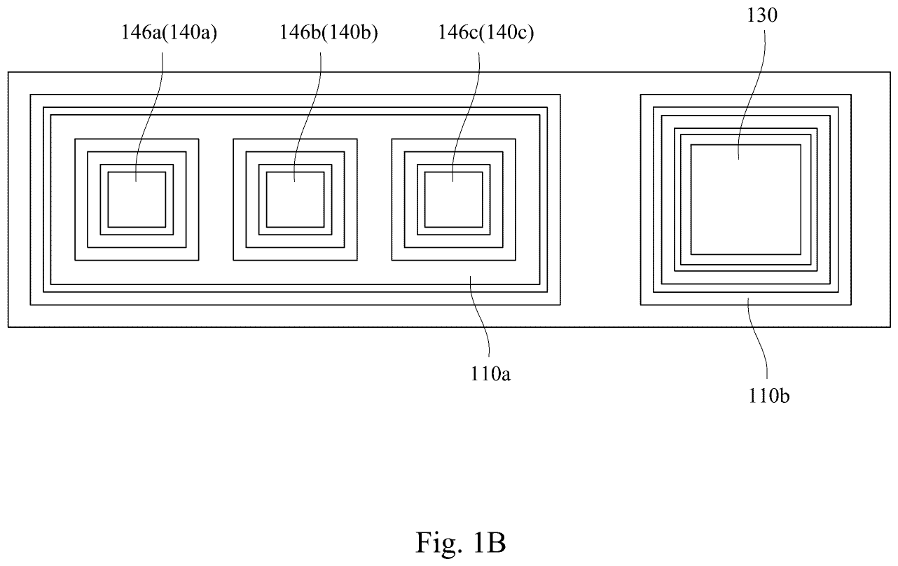

FIG. 1A is a cross-section diagram of a display element 100 according to one embodiment of the present disclosure. FIG. 1B is a top view of a first spacer 110a, a second spacer 110b and light-emitting diode (LED) structures 140a, 140b and 140c of the display element 100 in FIG. 1A. Referring to FIGS. 1A and 1B, the display element 100 includes the first spacer 110a, the second spacer 110b, first electrodes 120a, 120b and 120c, a second electrode 130, the LED structures 140a, 140b and 140c, a reflective layer 150, a first transparent molding layer 160 and a transparent conductive layer 170. In FIG. 1A and FIG. 1B, the numbers of the first electrodes and the LED structures are three separately, but are not intended to limit the present disclosure. The first electrodes 120a, 120b and 120c are surrounded by the first spacer 110a. The second electrode 130 is surrounded by the second spacer 110b. Materials of the first spacer 110a and the second spacer 110b may include a light-sensitive material which has a function of absorbing light. The first electrodes 120a, 120b and 120c and the second electrode 130 may include metals, such as silver (Ag), aluminum (Al), gold (Ag), a combination of the above, or similar materials. The LED structures 140a, 140b and 140c are located on the first electrodes 120a, 120b and 120c respectively, where the LED structure 140a includes a first semiconductor layer 142a, a multi-quantum well layer 144a and a second semiconductor layer 146a, the LED structure 140b includes a first semiconductor layer 142b, a multi-quantum well layer 144b and a second semiconductor layer 146b, and the LED structure 140c includes a first semiconductor layer 142c, a multi-quantum well layer 144c and a second semiconductor layer 146c. With the LED structure 140a as an example, the first semiconductor layer 142a is located on the first electrode 120a, the multi-quantum well layer 144a is located on the first semiconductor layer 142a, and the second semiconductor layer 146a is located on the multi-quantum well layer 144a.

The reflective layer 150 is located on a sidewall of the first spacer 110a facing the LED structures 140a, 140b and 140c. In some embodiments, materials of the reflective layer 150 may include the metals such as silver, aluminum, gold same as those included in the first electrodes 120a, 120b and 120c and the second electrode 130. In the above-mentioned embodiment, the reflective layer 150, the first electrodes 120a, 120b and 120c and the second electrode 130 may be formed by a same film layer. In other embodiments, the reflective layer 150 may also include non-metals with a strong light reflecting capacity. The first transparent molding layer 160 is located on the reflective layer 150 and surrounds the LED structures 140a, 140b and 140c, where top surfaces 147a, 147b and 147c of the second semiconductor layers 146a, 146b and 146c are higher than a top surface 162 of the first transparent molding layer 160. Materials of the first transparent molding layer 160 may include a highly transmittable molding material, such as polydimethylsiloxane (PDMS), but the present disclosure is not limited to this. The transparent conductive layer 170 is located on the top surface 162 of the first transparent molding layer 160 and the top surfaces 147a, 147b and 147c of the second semiconductor layer 146a, 146b and 146c, and the transparent conductive layer 170 extends to the second electrode 130. Materials of the transparent conductive layer 170 may include indium tin oxide (ITO), indium zinc oxide (IZO), a combination of the above, or other suitable material.

In addition, the display element 100 further includes a light-absorbing structure 180, a second transparent molding layer 190 and a substrate 200. The light-absorbing structure 180 is located on the transparent conductive layer 170 and surrounds top portions of the second semiconductor layers 146a, 146b and 146c. Materials of the light-absorbing structure 180 may include a light tight light-sensitive material for absorbing light emitted by the LED structures 140a, 140b and 140c and isolating the light emitted by each of the LED structures 140a, 140b and 140c, so that the light emitted by one of the LED structures 140a, 140b and 140c (for example, LED structure 140a) will not interfere with the light emitted by another LED structure (for example, adjacent LED structure 140b). The second transparent molding layer 190 is located on the transparent conductive layer 170 and surrounded by the light-absorbing structure 180. Materials of the second transparent molding layer 190 may include a highly transmittable molding material, such as polydimethylsiloxane (PDMS), but the present disclosure is not limited to this. The substrate 200 is located on the second transparent molding layer 190, and has a thickness of less than 0.5 mm.

Since the first electrodes 120a, 120b and 120c and the second electrode 130 of the display element 100 are in an exposed state when being manufactured completely, a bottom surface of one of the first electrodes 120a, 120b and 120c and a bottom surface of the second electrode 130 can be directly contacted and energized with a probe, so as to test one of the LED structures 140a, 140b and 140c separately without a need of bonding the one to a control circuit substrate before testing.

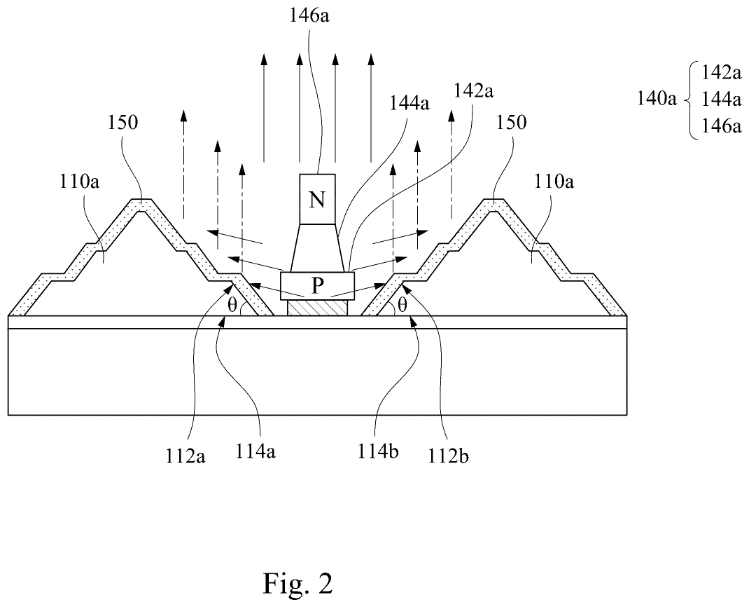

FIG. 2 is a drawing of partial enlargement of the first spacer 110a according to one embodiment of the present disclosure; Referring to FIG. 2, in this embodiment, sidewalls 112a and 112b of the first spacer 110a are stepped surfaces, and included angles θ between the sidewalls 112a and 112b and the lower surfaces 114a and 114b are 30-55 degrees respectively. In this angle range, since a reflective layer 150 is plated on the first spacer 110a, laterally-emitted light of the LED structure 140a can be reflected to be upward-emitted light, and a light emission efficiency in this angle range is the best. In this embodiment, sidewalls of each section of the stepped surfaces may be at different angles, and the included angles may become larger and larger as the sidewalls approach a top end of the first spacer 110a.

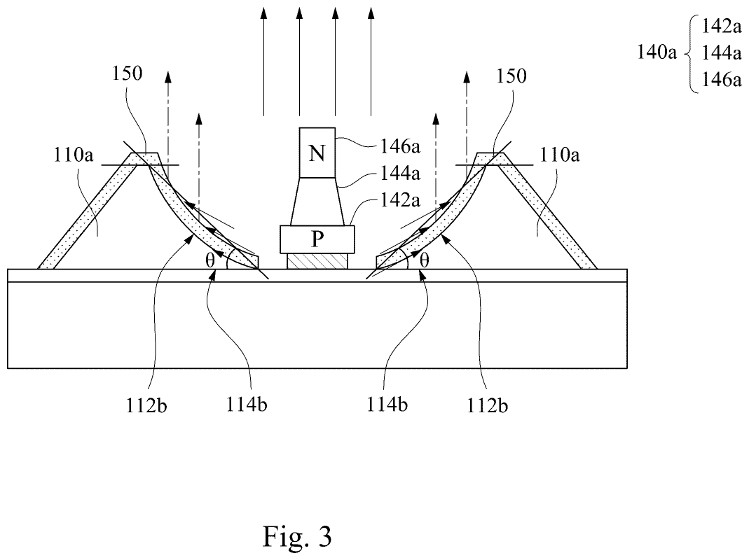

FIG. 3 is a drawing of partial enlargement of the first spacer 110a according to another embodiment of the present disclosure. Referring to FIG. 3, in this embodiment, the sidewalls 112a and 112b of the first spacer 110a are concave surfaces, and the included angles θ between the sidewalls 112a and 112b and the lower surfaces 114a and 114b are 30-55 degrees respectively. In this embodiment, a method of obtaining the angles θ is implemented by taking included angles between a connecting line, between an edge of the top surface of the first spacer 110a and edges of the lower surfaces 114a and 114b, and the lower surfaces 114a and 114b as the angles θ. In this embodiment, the sidewalls 112a and 112b of the concave surfaces are still capable of reflecting the laterally-emitted light of the LED structure 140a to be an upward-emitted light by the reflective layer 150.

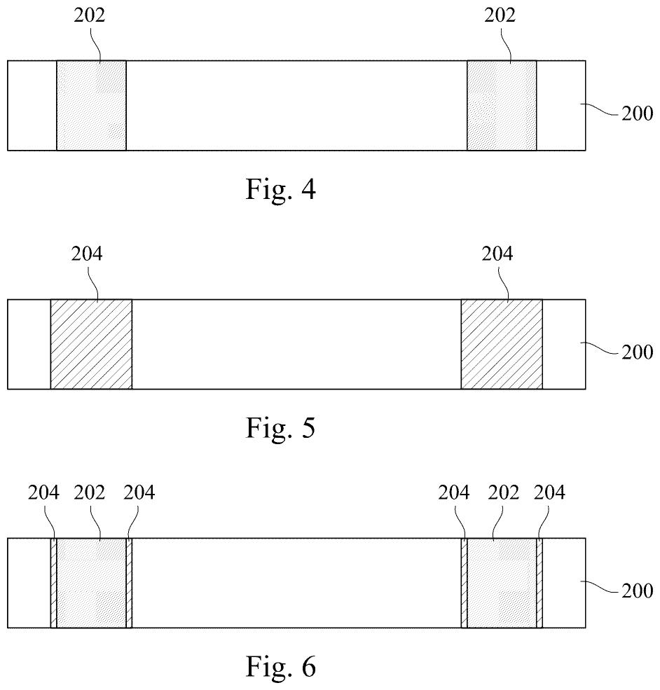

FIG. 4 is a drawing of partial enlargement of the display element 100 at block A according to one embodiment of the present disclosure. Referring to FIGS. 1A and 4, in this embodiment, the substrate 200 has a light-absorbing layer 202 inside, and the light-absorbing layer 202 is located on the light-absorbing structure 180. The light-absorbing layer 202 has a function similar to that of the light-absorbing structure 180. The light-absorbing layer 202 can absorb the light emitted by each of the LED structures 140a, 140b and 140c, so that the light emitted by one of the LED structures 140a, 140b and 140c (for example, the LED structure 140a) will not interfere with the light emitted by another LED structure (for example, the adjacent LED structure 140b). In some embodiments, the light-absorbing layer 202 may include a material same as that of the light-absorbing structure 180.

FIG. 5 is a drawing of partial enlargement of the display element 100 at block A according to another embodiment of the present disclosure. This embodiment differs from the embodiment in FIG. 4 in that the substrate 200 has a light-reflective layer 204 inside and no light-absorbing layer 202 inside, and the light-reflective layer 204 is located on the light-absorbing structure 180. The purpose of filling the light-reflective layer 204 in the substrate 200 is to allow the light-reflective layer 204 to reflect the light emitted by the LED structures 140a, 140b and 140c, so that the light emitted by one of the LED structures 140a, 140b and 140c (for example, the LED structure 140a) will not interfere with the light emitted by another LED structure (for example, the adjacent LED structure 140b). In some embodiments, the light-reflective layer 204 may include a metal material with a good light reflecting effect, such as silver, aluminum, gold, a combination of the above, or a similar material.

FIG. 6 is a drawing of partial enlargement of the display element 100 at block A according to yet another embodiment of the present disclosure. This embodiment differs from the embodiment in FIG. 4 in that the substrate 200 also has a light-reflective layer 204 inside in addition to the light-absorbing layer 202, and the light-reflective layer 204 is located on a sidewall of the light-absorbing layer 202. Since the substrate 200 has the light-absorbing layer 202 and the light-reflective layer 204 inside simultaneously, most of lateral light can be reflected away by the light-reflective layer 204, and the lateral light can be further absorbed by the rear light-absorbing layer 202. Further, the simultaneous presence of the light-absorbing layer 202 and the light-reflective layer 204 can increase the light output efficiency and save costs.

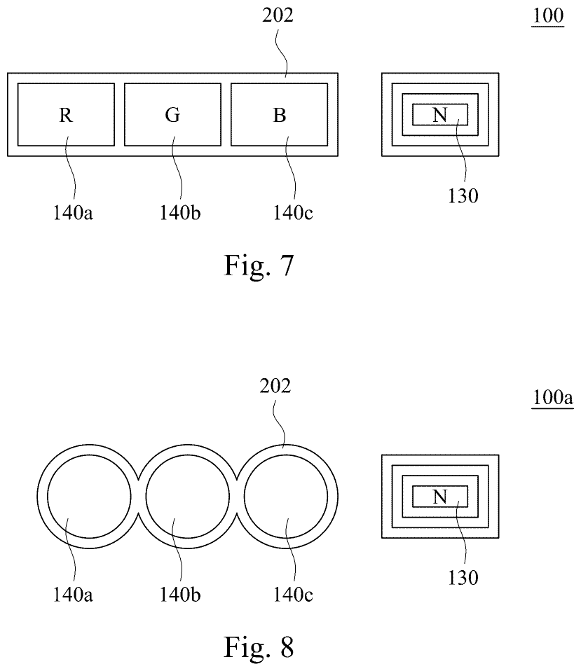

FIG. 7 is a top view of a method of the display element 100 according to one embodiment of the present disclosure. Referring to FIG. 1A and FIG. 7, in this embodiment, there are three LED structures 140a, 140b and 140c arranged in a column, the three LED structures are a red LED structure (such as the LED structure 140a), a green LED structure (such as the LED structure 140b) and a blue LED structure (such as the LED structure 140c) respectively, there are three first electrodes 120a, 120b and 120c, first semiconductor layers 142a, 142b, 142c of the three LED structures 140a, 140b and 140c are electrically connected to the three first electrodes 120a, 120b and 120c respectively, and second semiconductor layers 146a, 146b, 146c of the three LED structures 140a, 140b and 140c are electrically connected to the second electrode 130. In this embodiment, each subpixel (i.e., a part framed by the light-absorbing layer 202) is rectangular, but may be of other shapes, as described in detail below.

FIG. 8 is a top view of a display element 100a according to another embodiment of the present disclosure. Referring to FIGS. 1A and 8, this embodiment differs from the embodiment in FIG. 7 in that in this embodiment, each subpixel (i.e., a part framed by the light-absorbing layer 202) is circular.

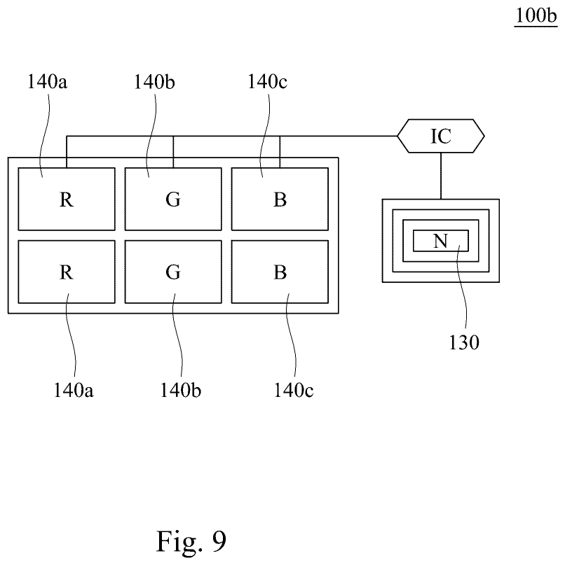

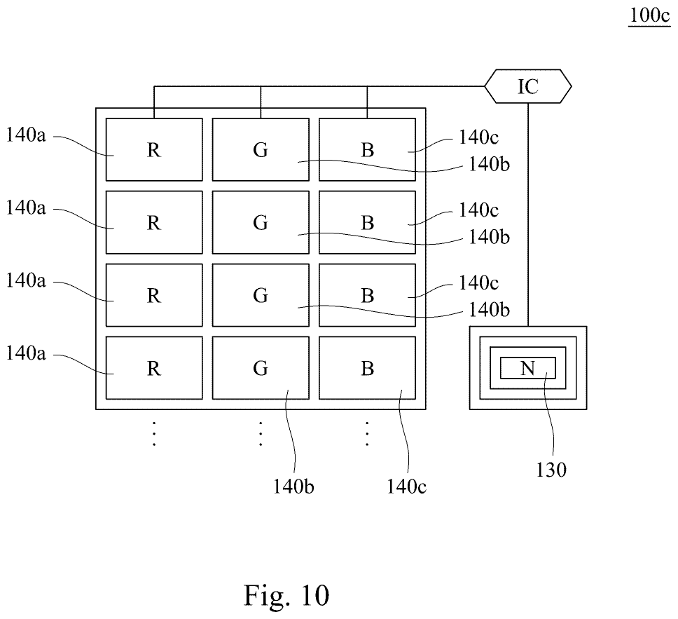

FIG. 9 is a top view of a display element 100b according to yet another embodiment of the present disclosure. FIG. 10 is a top view of a display element 100c according to still another embodiment of the present disclosure. Referring to FIG. 1A, FIG. 9 and FIG. 10, in some embodiments, there are a plurality of LED structures 140a, 140b and 140c arranged in a plurality of columns, the LED structures 140a, 140b and 140c in each of the columns include a red LED structure (such as the LED structure 140a), a green LED structure (such as the LED structure 140b) and a blue LED structure (such as the LED structure 140c) respectively, there are a plurality of first electrodes 120a, 120b and 120c, first semiconductor layers 142a, 142b, 142c of the LED structures 140a, 140b and 140c are electrically connected to the first electrodes 120a, 120b and 120c respectively, and second semiconductor layers 146a, 146b, 146c of the LED structures 140a, 140b and 140c are electrically connected to the second electrode 130. In the embodiment of FIG. 9, there are six LED structures 140a, 140b and 140c arranged in two columns, so that the number of the first electrodes 120a, 120b and 120c (refer to FIG. 1A) is six, and the number of the second electrode 130 is one (i.e., the second semiconductor layers 146a, 146b, 146c of all the LED structures 140a, 140b and 140c are copolar, and controlled by a control circuit IC). In the embodiment of FIG. 10, there may be more LED structures 140a, 140b and 140c (for example, twelve), and every three LED structures are arranged in a column. Each column of the LED structures includes a red LED structure (for example, the LED structure 140a), a green LED structure (for example, the LED structure 140b) and a blue LED structure (for example, the LED structure 140c). In some embodiments, the red LED structure 140a, the green LED structure 140b and the blue LED structure 140c are arranged in order from left to right, but in other embodiments, the positions of the red LED structure 140a, the green LED structure 140b and the blue LED structure 140c can also be changed in any order, as long as each column of the LED structures includes the red LED structure 140a, the green LED structure 140b, and the blue LED structure 140c.

It should be understood that the connection relations, materials and functions of the elements that have been described will not be repeated, which is explained first. A manufacturing method of the display element 100 is described in the following description.

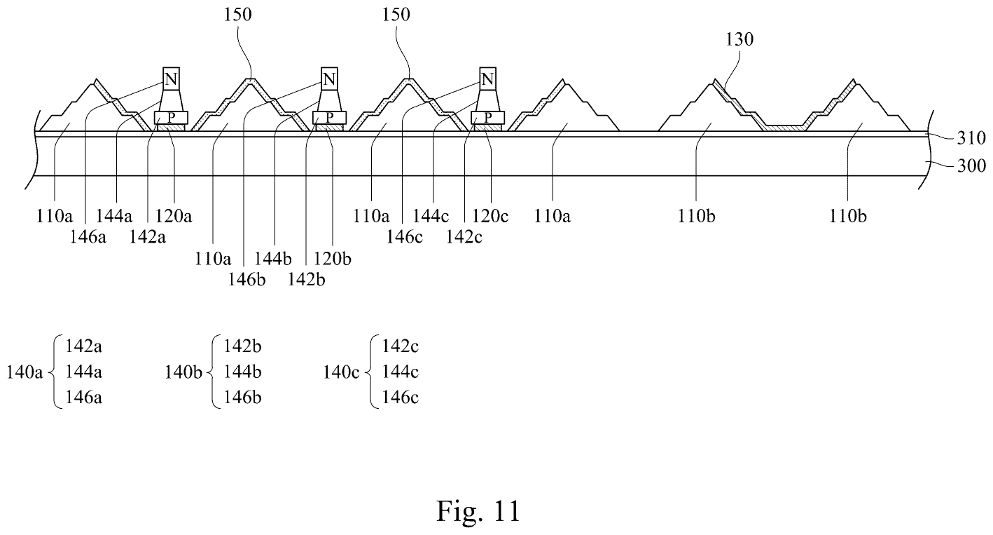

FIGS. 11-16 are cross-section diagrams of the display element 100 during manufacturing according to one embodiment of the present disclosure. Referring to FIG. 11, the manufacturing method of the display element 100 includes: a temporary jointing layer 310 is formed on a carrier plate 300. Next, a first spacer 110a and a second spacer 110b are formed on the temporary jointing layer 310. The formation of the first spacer 110a and the second spacer 110b may be implemented by using a patterned light-sensitive material, but the present disclosure is not limited to this. Then, first electrodes 120a, 120b and 120c and a second electrode 130 are formed on the temporary jointing layer 310, where the first electrodes 120a, 120b and 120c are surrounded by the first spacer 110a, and the second electrode 130 is surrounded by the second spacer 110b. Then, a reflective layer 150 is formed on a sidewall of the first spacer 110a. In some embodiments, when the reflective layer 150 is formed by materials same as those of the first electrodes 120a, 120b and 120c and the second electrode 130 (i.e., the materials are all metallic materials, such as silver, aluminum and gold), the formation of the reflective layer 150 and the formation of the first electrodes 120a, 120b and 120c and the second electrode 130 are implemented simultaneously. Then, LED structures 140a, 140b and 140c are formed on the first electrodes 120a, 120b and 120c, and with the LED structure 140a as an example, the LED structure 140a includes a first semiconductor layer 142a, a multi-quantum well layer 144a and a second semiconductor layer 146a that are stacked in sequence.

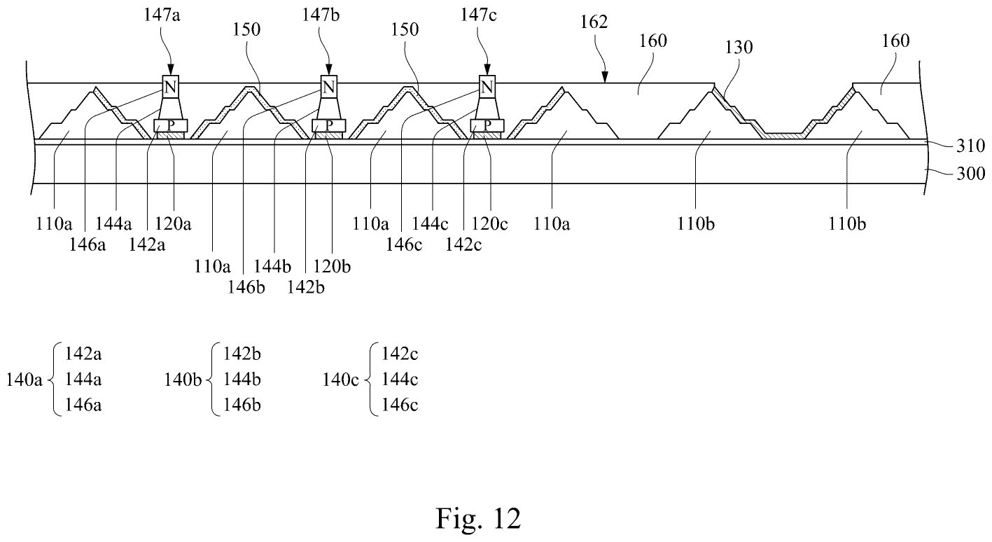

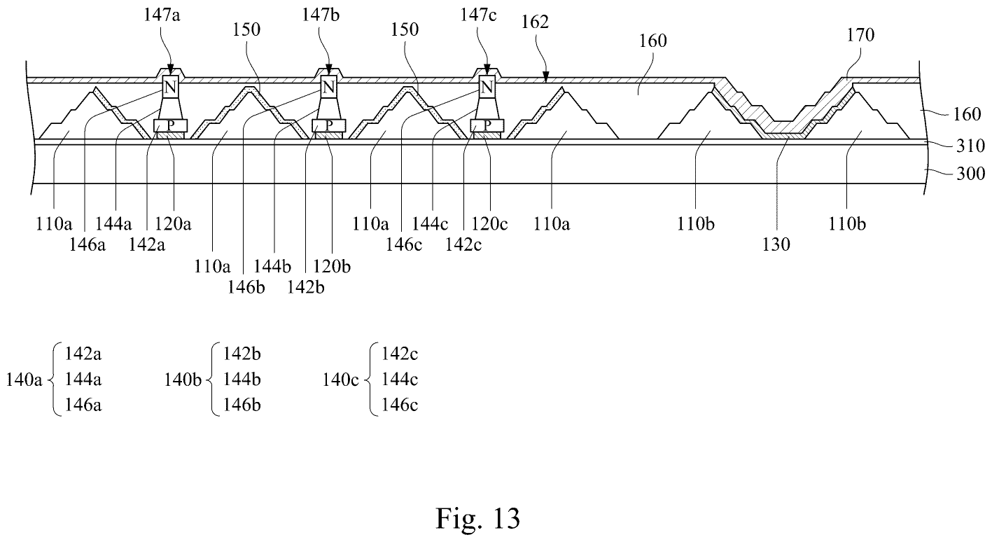

Referring to FIG. 12, then, a first transparent molding layer 160 is formed on the reflective layer 150 and around the LED structures 140a, 140b and 140c, where top surfaces 147a, 147b, 147c of the second semiconductor layers 146a, 146b, 146c are higher than a top surface 162 of the first transparent molding layer 160. The purpose of allowing the top surfaces 147a, 147b, 147c of the second semiconductor layers 146a, 146b, 146c to be higher than the top surface 162 of the first transparent molding layer 160 is to achieve that when the transparent conductive layer 170 is then formed (refer to FIG. 13), the transparent conductive layer 170 can be in contacted with the second semiconductor layers 146a, 146b, 146c and thus is electrically connected to the second semiconductor layers 146a, 146b, 146c. The first transparent molding layer 160 can be formed by a yellow-light process so that the first transparent molding layer 160 will not be formed on the second electrode 130.

Referring to FIG. 13, a transparent conductive layer 170 is then formed on the top surface 162 of the first transparent molding layer 160 and on the top surfaces 147a, 147b, 147c of the second semiconductor layers 146a, 146b, 146c. The transparent conductive layer 170 extends to the second electrode 130 and is electrically connected to the second semiconductor layers 146a, 146b, 146c and the second electrode 130. The transparent conductive layer 170 can be formed by a deposition process, such as physical vapor deposition (PVD), followed by patterned deposition, which is not limited to this. The transparent conductive layer 170 forms an Ohmic contact with the second electrode 130, thereby reducing a resistance between the second electrode 130 and the second semiconductor layers 146a, 146b, 146c.

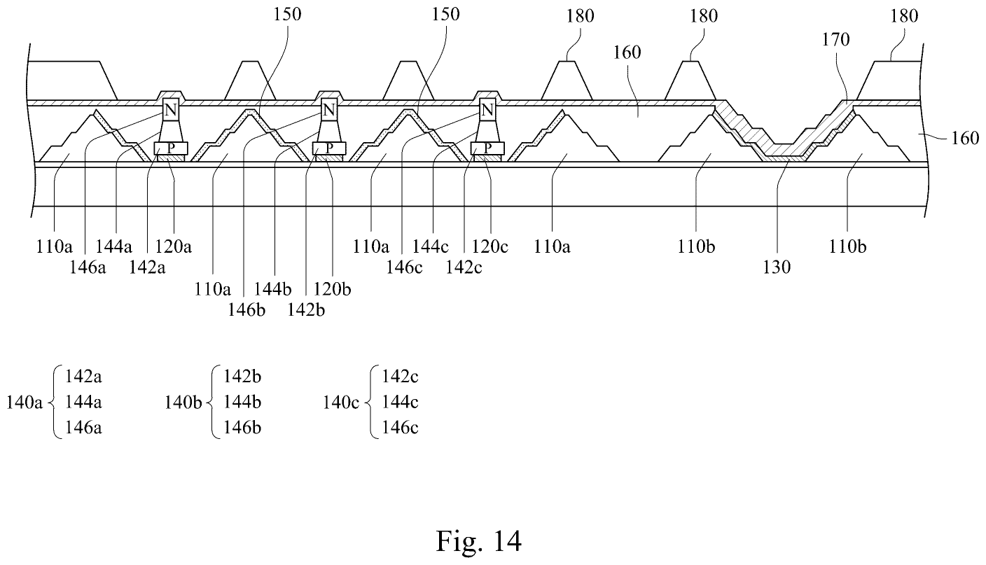

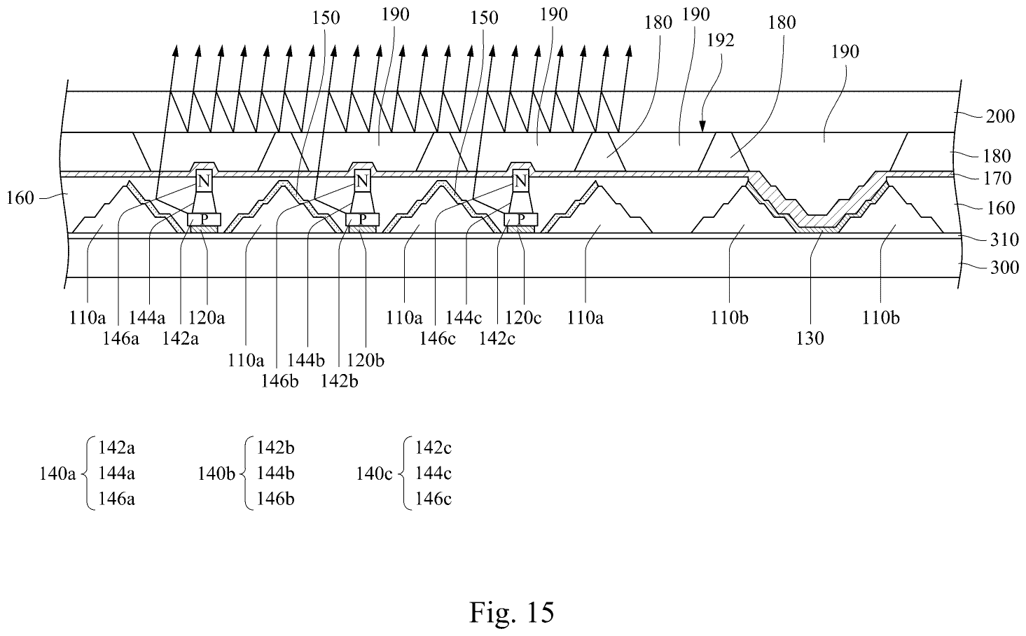

Referring to FIGS. 14 and 15, at least one light-absorbing structure 180 is then formed on the first transparent molding layer 160 and the transparent conductive layer 170. In the formation of the light-absorbing structure 180, the light tight light-sensitive material can be patterned through the yellow light process. Next, a second transparent molding layer 190 is formed on the first transparent molding layer 160 and the transparent conductive layer 170. At this time, the second transparent molding layer 190 will be formed on a surface of the transparent conductive layer 170 which is not covered by the light-absorbing structure 180 (that is, will also be formed above the second electrode 130), and since the second transparent molding layer 190 is high in flatness, a top surface 192 will be roughly flat after the formation of the second transparent molding layer 190. Next, a substrate 200 is arranged on the top surface 192 of the second transparent molding layer 190. At this time, the substrate 200 still has a certain thickness.

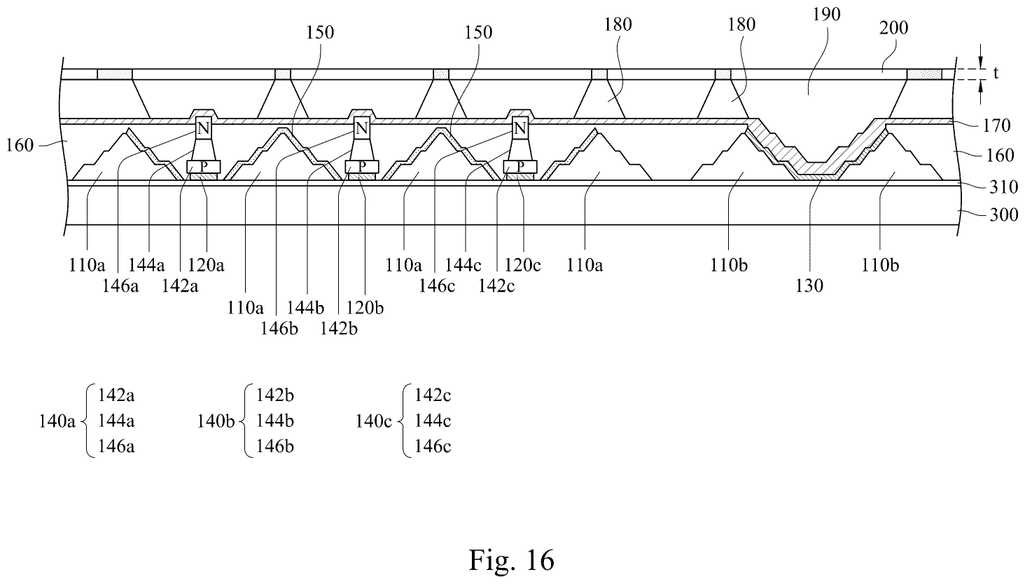

Referring to FIG. 16, after the substrate 200 is jointed, the substrate 200 is thinned so that the substrate 200 has a thickness t of less than 0.5 mm. The thinned substrate 200 can reduce a phenomenon of diffusion of light emitted by the LED structures 140a, 140b and 140c in the substrate 200. After the substrate 200 is thinned, an opening can be further formed in the substrate 200. This process is also known as a through glass via (TGV) process. Then, depending on different embodiments, optionally, a light-absorbing material can be filled in the opening of the substrate 200 (as shown in the embodiment of FIG. 4), a light-reflective material can be filled in the opening of the substrate 200 (as shown in the embodiment of FIG. 5), alternatively, the light-reflective material is plated on a sidewall of the opening first and then the light-absorbing material is filled in the opening (as shown in the embodiment of FIG. 6).

Referring to FIGS. 1A and 16, after the substrate 200 of FIG. 16 is formed, the temporary jointing layer 310 and the carrier plate 300 are removed. After the temporary jointing layer 310 and the carrier plate 300 are removed, the display element 100 of FIG. 1A is completely manufactured. The display element 100 can then be bonded to an additional control circuit substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A display element, comprising:
a first spacer;
a second spacer, located on one side of the first spacer;
at least one first electrode, surrounded by the first spacer;
a second electrode, surrounded by the second spacer;
at least one light-emitting diode (LED) structure, located on the first electrode, and comprising:
a first semiconductor layer, located on the first electrode;
a multi-quantum well layer, located on the first semiconductor layer; and
a second semiconductor layer, located on the multi-quantum well layer;
a reflective layer, located on a sidewall of the first spacer facing the LED structure;
a first transparent molding layer, located on the reflective layer and surrounding the LED structure, wherein a top surface of the second semiconductor layer is higher than a top surface of the first transparent molding layer; and
a transparent conductive layer, located on the top surface of the transparent molding layer and the top surface of the second semiconductor layer, and extending to the second electrode.

2. The display element according to claim 1, wherein the sidewall of the first spacer is a stepped surface or a concave surface.

3. The display element according to claim 1, wherein an included angle between the sidewall of the first spacer and a lower surface is 30-55 degrees.

4. The display element according to claim 1, further comprising:
a light-absorbing structure, located on the transparent conductive layer and surrounding a top portion of the second semiconductor layer.

5. The display element according to claim 4, further comprising:
a second transparent molding layer, located on the transparent conductive layer and surrounded by the light-absorbing structure.

6. The display element according to claim 5, further comprising:
a substrate, located on the second transparent molding layer.

7. The display element according to claim 6, wherein the substrate has a light-absorbing layer inside, and the light-absorbing layer is located on the light-absorbing structure.

8. The display element according to claim 7, wherein the substrate has a light-reflective layer inside, and the light-reflective layer is located on a sidewall of the light-absorbing layer.

9. The display element according to claim 7, wherein the substrate has a light-reflective layer inside, and the light-absorbing layer is located on the light-absorbing structure.

10. The display element according to claim 6, wherein the substrate has a thickness of less than 0.5 mm.

11. The display element according to claim 1, wherein the reflective layer, the first electrode and the second electrode are formed by a same film layer.

12. The display element according to claim 1, wherein there are three LED structures arranged in a column, the three LED structures are a red LED structure, a green LED structure and a blue LED structure respectively, there are three first electrodes, the first semiconductor layers of the three LED structures are electrically connected to the three first electrodes respectively, and the second semiconductor layers of the three LED structures are electrically connected to the second electrode.

13. The display element according to claim 1, wherein there are a plurality of LED structures arranged in a plurality of columns, and the LED structures in each of the columns comprise a red LED structure, a green LED structure and a blue LED structure, there are a plurality of first electrodes, the first semiconductor layers of the LED structures are electrically connected to the first electrodes respectively, and the second semiconductor layers of the LED structures are electrically connected to the second electrode.

14. A manufacturing method of a display element, comprising:
forming a temporary jointing layer on a carrier plate;
forming a first spacer and a second spacer on the temporary jointing layer;
forming a reflective layer on a sidewall of the first spacer;
forming at least one first electrode and a second electrode on the temporary jointing layer, wherein the first electrode is surrounded by the first spacer and the second electrode is surrounded by the second spacer;
forming a LED structure on the first electrode, wherein the LED structure comprises a first semiconductor layer, a multi-quantum well layer and a second semiconductor layer that are stacked in sequence;
forming a first transparent molding layer on the reflective layer and around the LED structure, wherein a top surface of the second semiconductor layer is higher than a top surface of the first transparent molding layer;
forming a transparent conductive layer on the top surface of the first transparent molding layer and the top surface of the second semiconductor layer, wherein the transparent conductive layer extends to the second electrode; and
removing the temporary jointing layer and the carrier plate.

15. The manufacturing method of a display element according to claim 14, further comprising:
forming at least one light-absorbing structure on the first transparent molding layer and the transparent conductive layer;
forming a second transparent molding layer on the first transparent molding layer and the transparent conductive layer;
forming a substrate on the second transparent molding layer; and
forming an opening in the substrate.

16. The manufacturing method of a display element according to claim 15, further comprising:
thinning the substrate so that the substrate has a thickness of less than 0.5 mm.

17. The manufacturing method of a display element according to claim 15, further comprising:
filling a light-absorbing material in the opening of the substrate.

18. The manufacturing method of a display element according to claim 15, further comprising:
filling a light-reflective material in the opening of the substrate.

19. The manufacturing method of a display element according to claim 15, further comprising:
plating a light-reflective material on a sidewall of the opening of the substrate; and
filling a light-absorbing material in the opening of the substrate.
